(19) United States
(12) Patent Application Publication
(10) Pub. No.: US 2012/0132805 A1
(43) Pub. Date: May 31, 2012

(54) ELECTRONIC CIRCUIT FOR BIASING AND READING A RESISTIVE THERMAL DETECTOR

(75) Inventors: Gilles CHAMMINGS, Grenoble (FR); Gaëlle Repellin, Meaudre (FR); Michaël Tchagaspanian, Saint Ismier (FR)

(73) Assignee: COMMISSARIAT A L'ENERGIE ATOMIQUE ET AUX ENE ALT, Paris (FR)

(21) Appl. No.: 13/295,597

(22) Filed: Nov. 14, 2011

(30) Foreign Application Priority Data
Nov. 29, 2010 (FR) 10 59873

(51) Int. Cl. H01L 27/146; G01K 7/16

(52) U.S. Cl. 250/332; 374/185; 374/E07.018

(57) ABSTRACT

An electronic circuit, for biasing and reading at least one resistive thermal detector, comprising:
biasing means able to bias the resistive thermal detector by making a biasing current of substantially constant value flow in the resistive thermal detector when the electrical resistance thereof varies;
conversion means able to convert a voltage at the terminals of the resistive thermal detector into a current, comprising at least one MOS-type transistor the gate of which is electrically connected to one of the terminals of the resistive thermal detector;
means of generating a base clipping voltage electrically connected to the source of the MOS-type transistor of the conversion means.

### TECHNICAL FIELD

The invention concerns the field of temperature measurement and imaging, such as infrared imaging. The invention concerns more particularly non-cooled infrared imager with resistive thermal detectors.

### PRIOR ART

An infrared imager with resistive thermal detectors such as bolometers comprise a matrix of pixels each comprising a resistive thermal detector used as an infrared radiation detector and which reacts to a variation in temperature through a variation in its electrical resistance. The imager also comprises an electronic reading circuit performing the acquisition, processing and evaluation of the signal supplied by the detector, that is to say the variation in the electrical resistance thereof.

The architecture of a pixel 10 of such an imager comprising, in this example, a bolometer 12 and an associated reading circuit, is shown in FIG. 1.

The bolometer 12 comprises a first terminal to which a biasing voltage Vdt is applied and a second terminal electrically connected to the source of an NMOS transistor 14 able to voltage bias the bolometer 12. The drain of the NMOS transistor 14 is electrically connected to a switch 16 that is closed when a temperature measurement is made by the bolometer 12.

A current base clipping circuit 18 is disposed at the head of each column of pixels in the matrix of pixels. Each circuit 18 comprises a thermalised bolometer 20 comprising a first terminal to which a supply voltage Vdd is applied and a second terminal electrically connected to the source of a PMOS transistor 22. A biasing voltage Geb is applied to the gate of the PMOS transistor 22. The voltage Vdt can be used paired with the voltage Gtd in order to adjust the biasing of the bolometer 12. The drain of the PMOS transistor 22 is electrically connected to a bus 24 common to all the pixels in the column and on which the circuit 18 outputs a base clipping current Ieb. The pixel 10 is electrically connected to the bus 24 by means of the switch 16. Finally, the bus 24 is electrically connected, at the column base (opposite to the circuit 18), to a circuit 26 for processing the measurement currents outputted by the pixels in the column.

In this architecture, the voltage biasing of the bolometer 12 is achieved by means of the NMOS transistor 14. The biasing voltage applied to the bolometer 12 is controlled by means of a voltage Gdt applied to the gate of this NMOS transistor 14, referred to as the injection or biasing transistor. The voltage biasing of the bolometer 12 makes it possible to define an average current Ibolo passing through the bolometer 12. The voltage Gdt is chosen so that the operating point of the injection transistor 14 is such that the latter functions at the saturation limit.

When the bolometer 12 is subjected to a temperature variation to be measured, this temperature variation causes a variation in its electrical resistance. Given that the bolometer 12 is voltage biased, this variation in its electrical resistance then results in a variation in the current passing through the bolometer 12. The useful information, that is to say the temperature variation measured, is therefore contained in the fluctuations of this current, which is centred around the average value Ibolo defined by the voltage biasing. It is therefore the bolometric current, that is to say the current passing through the bolometer, which is the image of the temperature variation measured by the bolometer 12 and constitutes the quantity processed by the reading circuit associated with the bolometer.

The circuit 18 makes it possible to make a base clipping of the bolometric current. This is because the current supplied by the bolometer 12 has a high common mode around which the small fluctuations in the signal representing the temperature fluctuations measure are situated. The base clipping circuit 18 is therefore used to eliminate the common mode of the bolometric current in order to keep only the useful part thereof. By closing the switch 16, the drain of the injection transistor 14 is electrically connected to the bus 24 and to the circuit 18. The base clipping current Ieb outputted by the circuit 18 is added to that outputted by the bolometer 12, which makes it possible to eliminate the common mode of the current supplied by the bolometer 12 (this elimination of the common mode corresponds to the base clipping operation) and therefore to obtain at the column base a base clipped current corresponding solely to the measurement of the temperature variation performed by the bolometer 12, outputted to the processing circuit 26.

The processing circuit 26 then performs an integration of the base clipped current via an integrating subcircuit of the circuit 26. The result of this integration is then supplied in the form of a voltage containing the information supplied by the bolometer. This voltage is then sent to a bus, which sequentially recovers all the voltages associated with all the sensors (bolometers) in the matrix of the imager. This sequence of “pixel values” is then sent into a video amplifier in order to reconstitute and display the image captured by the matrix of pixels of the imager.

The architecture of the pixel 10 previously described however have unsatisfactory performances, in particular in terms of signal to noise ratio. This is because the signal (the infrared radiation) captured by the imager will necessary undergo degradation (noise) due to the bolometer itself and to the reading circuit, resulting in a reduction in the signal to noise ratio on the signal obtained in the end. This interference is substantial in particular when the bolometer has a low average resistance. In this case, the degradation caused by the reading electronics is greater than that caused by the bolometer itself. It is therefore in this case the electronic reading circuit that limits the performance of the pixel.

It is observed in fact that the reduction of the average bolometer resistance causes a degradation in the injection efficiency of the injection transistor 14, which is equal to:

$$\frac{gm \cdot {R}_{bolo}}{1 + gm \cdot {R}_{bolo}} ,$$

with

gm: transconductance of the injection transistor 14;

R_{bolo}: resistance of the bolometer 12.

This degradation results in poor transmission by the injection transistor 14 of the measurement current supplied by the bolometer 12.

In addition, if R_{bolo} decreases, then the current noise caused by the bolometer Iₙₒᵢₛₑ_{_{—}}_{bolo} also decreases.

However, Iₙₒᵢₛₑ_{_{—}}_{bolo}_{²}=I^{1/f}_{²}+Iₜₕₑᵣₘₐₗ_{²}. When R_{bolo} decreases the 1/f noise decreases more than the thermal noise increases. The bolometer 12 is therefore less noisy.

Moreover, if I_{bolo} increases, then the current noise caused by the injection transistor 14 increases. The noise of a transistor consists of two components: the thermal noise (white noise) and the 1/f noise. It is expressed according to the following quantities: 1/R_{bolo}, I_{ds}, W/L and W. L, with

Ids: drain-source current of the transistor;

W: width of the transistor;

L: gate length of the transistor;

The injection transistor 14 therefore becomes noisier.

In the end, the noise of the reading circuit becomes predominant with respect to the bolometer noise. Consequently the signal to noise ratio of the pixel decreases, the resolution of the imager is less good and the image captured degrades.

To remedy this, it is therefore sought to increase the performance of the electronics of the bolometer reading circuit. The main objective is therefore to reduce the noise contributed by the reading circuit for the purpose of improving the signal to noise ratio of the pixel.

The solutions proposed to reduce the noise of an MOS transistor consist essentially of using an SOI technology and/or acting on its size. This is because, by increasing the size of a transistor, it becomes less noisy. The tendency is therefore to increase its width W and its gate length L.

However, acting on the dimensions of the components proves to be tricky, in the particular in the imaging field. This is because the imager consists of a matrix of pixels: all the components situated in the pixel have dimensions constrained by the size of the pixel. Some components (circuit 18 and circuit 26 in the example in FIG. 1), which are common to several pixels, may nevertheless be placed outside the pixels, at the base and/or head of the column and/or row: there is then no longer any constraint on their size. However, this does not apply to components where it is sought to reduce the noise and which are arranged close to the bolometer. These components are situated in the pixel and manipulation of their dimensions is therefore limited.

Although tricky, it is possible, to a certain extent, to increase the dimensions of these transistors in order to reduce their noise. Nevertheless, when the size of the components exceeds that of one pixel, it then becomes necessary to modify the global architecture of the pixels by carrying out a sharing of the components between two adjacent pixels. However, such sharing of components between pixels involves constraints on the use of the imager. It is for example no longer possible to use the “rolling shutter” mode, which is a method of scanning the pixel matrix in which several consecutive rows undergo simultaneous acquisition, and which therefore requires that each pixel has its own reading electronics, that is to say not shared with other pixels in the matrix.

### DISCLOSURE OF THE INVENTION

One aim of the present invention is to propose a new electronic circuit for biasing and reading at least one resistive thermal detector such as a bolometer, forming a new pixel architecture of an imaging device, improving the signal to noise ratio of the captured signal without increasing the sizes of the electronic components, and in particular of the transistors, of the pixels.

For this purpose, an electronic circuit is proposed for biasing and reading at least one resistive thermal detector (for example a bolometer) comprising:
biasing means able to polarise the resistive thermal detector by making a biasing current with a substantially constant value flow in the resistive thermal detector when there is a variation in its electrical resistance;
conversion means able to convert a voltage at the terminals of the resistive thermal detector into a current.

An electronic circuit for biasing and reading at least one resistive thermal detector is also proposed, comprising:
biasing means able to bias the resistive thermal detector by making a biasing current with a substantially constant value flow in the resistive thermal detector when there is a variation in its electrical resistance;
conversion means able to convert a voltage at the terminals of the resistive thermal detector into a current, comprising at least one transistor of the MOS type, which may be called the second transistor, the gate of which is electrically connected to one of the terminals of the resistive thermal detector;
means of generating a base clipping voltage electrically connected to the source of the MOS-type transistor of the conversion means.

Such an electronic biasing and reading circuit can be used for any type of resistive thermal detector, for example a bolometer or a microbolometer or any other resistor variable with temperature.

This new electronic circuit performs a biasing of the detector by means of a direct current, which makes it possible to translate the temperature variations measured by the detector into voltage variations at the terminals thereof. These voltage variations are next converted into current by the conversion means, for example using the transconductance of a MOS transistor connected as a “common source”. Thus, as in the reading circuits of the prior art, the current therefore remains the quantity that is the image of the temperature variations measured. However, here, this current is obtained in two conversion steps: variation in resistance converted into variation in voltage, and then converted into variation in current.

This electronic biasing and reading circuit uses a current biasing of the detector that is completely independent of the measurement of the detector, which makes it possible to dissociate the constraints on the detector biasing means and the constraints on the measuring means. Thus this electronic biasing and reading circuit makes it possible to supply the detector with a biasing current of necessary intensity for it to function optimally from a signal to noise ratio point of view, while using a current low enough in the measuring means for these means to be less noisy than in the circuits of the prior art.

Moreover, this electronic biasing and reading circuit is adapted to make a new type of base clipping of the common mode of the quantity to be read. The average value of the measurement current is not longer imposed by the detector but solely by the measuring means. Thus a current base clipping may be partially made for example by simply controlling the voltage of one of the terminals of an MOS transistor of these measuring means. It is therefore no longer necessary to have recourse to the base clipping structure of the prior art (the circuit 18 shown in FIG. 1) situated at the column head.

The architecture of this new electronic biasing and reading circuit makes it possible to read the information of the resistive thermal detector and to carry out the base clipping of the signal, and has the advantage of reducing the noise of the reading electronics of the detector, the whole without making the overall architecture of the pixel complex, without requiring resizing of the electronic components and without requiring a modification to the global matrix architecture of the pixels.

This new electronic biasing and reading circuit also makes it possible to reduce the noise of the electronics of the pixel:
without impairing the measurement on the current of the detector, or bolometric current,
keeping the characteristics (current passing through the detector and voltage at the terminals of the detector) affording optimum functioning of the detector,
without calling into question the global matrix architecture of the imager.

The noise of the electronics that was, in the circuits of the prior art, predominant with respect to the noise of the detector is therefore relatively reduced. The signal to noise ratio of the measurement performed is improved, enhancing the quality and resolution of the image obtained.

This circuit also reduces the non-linearities compared with the circuits of the prior art.

Compared with the circuits of the prior art, the new electronic biasing and reading circuit does not comprise any added equipment. For example, the number of MOS transistors able to form the biasing means and the reading means may be identical to those of the biasing and reading circuits of the prior art.

In addition, the structure of this electronic biasing and reading circuit does not require sharing the electronic components between several pixels. Thus an imager comprising such electronic circuits can make a scanning of the matrix of pixels in accordance with the “rolling shutter” mode, which cannot be carried out in the case of a sharing of the electronic components between several pixels.

The biasing means may comprise at least one first transistor of the MOS type, the source or drain of which is electrically connected to one of the terminals of the resistive thermal detector.

The conversion means may comprise at least one second transistor of the MOS type, the gate of which may be electrically connected to said at least one of the terminals of the resistive thermal detector. Thus the voltage at the terminals of the detector can be converted into a measuring current via the transconductance of the second MOS-type transistor. In addition, the use of an MOS transistor on the measuring arm of the circuit makes it possible to benefit from a floating voltage on this arm (the drain voltage of the MOS transistor in saturation), to isolate the pixels from one another from a voltage point of view and therefore avoid disturbing a pixel during the reading of another pixel in the matrix. The advantage of a pixel keeping a high output impedance is therefore kept since the noise of the pixel is reduced as well as the contribution of the amplitude by improving the rejection of the inherent noise of the amplifier. The total signal to noise ratio is therefore improved.

This circuit also makes it possible to make the biasing current independent with respect to the reading current obtained, which makes it possible to have a low measuring current and therefore to improve the signal to noise ratio of the circuit.

The first MOS-type transistor may be an NMOS transistor and the second MOS-type transistor may be PMOS transistor. In a variant, the first MOS-type transistor may be a PMOS transistor and the second MOS-type transistor may be an NMOS transistor.

In another variant, the first and second MOS-type transistors may be transistors of the same type, PMOS or NMOS.

The electronic circuit may also comprise means of generating a base clipping voltage electrically connected to the source of the second MOS-type transistor.

The electronic circuit may also comprise at least one switch electrically connected to the second MOS-type transistor and able to establish and interrupt a flow of current between the second MOS-type transistor and an output on which the current outputted by the conversion means is intended to be sent.

It is also proposed an electronic imager comprising a matrix of pixels, each pixel comprising at least one resistive thermal detector, and also comprising a plurality of electronic biasing and reading circuits for at least one resistive thermal detector as defined previously.

Each electronic biasing and reading circuit may be associated with a single pixel comprising a resistive thermal detector intended to be biased and read by said electronic biasing and reading circuit, the biasing means and the conversion means of said electronic biasing and reading circuit being able to be arranged in said pixel.

In a variant, each electronic biasing and reading circuit may be associated with several pixels each comprising a resistive thermal detector intended to be biased and read by said electronic biasing and reading circuit, each electronic biasing and reading circuit being able to comprise several conversion means, each of said conversion means being able to convert a voltage at the terminals of the resistive thermal detector of one of said pixels into a current and being able to be arranged in said one of said pixels, and in which the biasing means of each electronic biasing and reading circuit may be common to several pixels and may be able to bias the resistive thermal detectors of said pixels by causing a biasing current with a substantially constant value to flow in the resistive thermal detectors of said pixels when there is a variation in the electrical resistance of the resistive thermal detectors of said pixels.

In this variant, the biasing means of each electronic biasing and reading circuit may be arranged outside said pixels.

In addition, each of said pixels may also comprise at least one switch able to establish and interrupt a flow of said current of substantially constant value between the resistive thermal detector of said pixel and the biasing means of said pixel.

The biasing means of each electronic biasing and reading circuit may also comprise at least one thermalised resistive thermal detector able to modify the value of said biasing current.

The resistive thermal detectors may be able to measure infrared radiation.

The resistive thermal detectors may be bolometers.

Finally, it is also proposed a method of measuring a temperature by means of at least one resistive thermal detector, comprising at least the steps of:
biasing the resistive thermal detector by causing a biasing current of substantially constant value to flow in the resistive thermal detector when there is a variation in the electrical resistance of the resistive thermal detector;
reading a voltage at the terminals of the resistive thermal detector exposed to the temperature to be measured;
converting the voltage read at the terminals of the resistive thermal detector into a current corresponding to the temperature measurement.

The conversion step may be performed by an MOS-type transistor the gate of which is electrically connected to one of the terminals of the resistive thermal detector. A base clipping voltage may be applied to the source of the MOS transistor.

### BRIEF DESCRIPTION OF THE DRAWINGS

The present invention will be better understood from a reading of the description of example embodiments given purely indicatively and in no way limitatively, referring to the accompanying drawings, in which:

FIG. 1 shows the architecture of a pixel of a matrix of an infrared imager with bolometers and an associated reading circuit according to the prior art,

FIG. 2 shows an electronic biasing and reading circuit for a resistive thermal detector of a pixel of an imager, according to a first embodiment,

FIG. 3 shows graphically the conversion of a voltage variation at the terminals of a resistive thermal detector into a variation in current by the electronic biasing and reading circuit of a resistive thermal detector,

FIG. 4 shows graphically the various conversion operations performed within a pixel comprising an electronic biasing and reading circuit for a resistive thermal detector,

FIG. 5 shows an electronic biasing and reading circuit of a resistive thermal detector of a pixel of an imager according to a variant of the first embodiment,

FIG. 6 shows an electronic biasing and reading circuit of a resistive thermal detector of a pixel of an imager according to a second embodiment,

FIGS. 7 to 9 show an electronic biasing and reading circuit of a resistive thermal detector of a pixel of an imager according to different variants of the second embodiment,

FIG. 10 shows an imager comprising a matrix of pixels and electronic biasing and reading circuits of resistive thermal detectors.

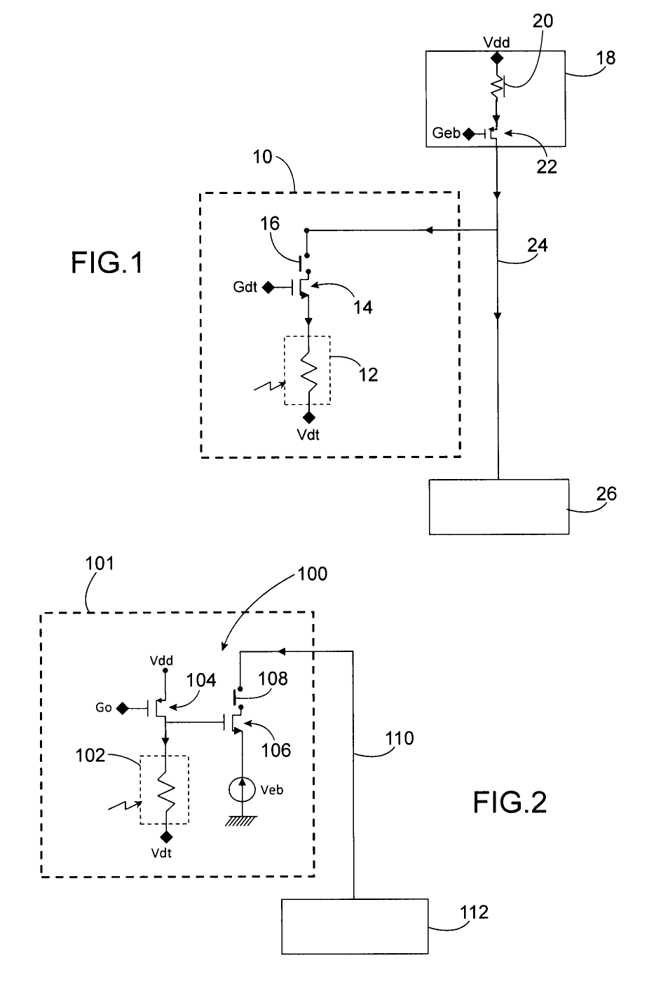

Identical, similar or equivalent parts of the different figures described below bear the same numerical references so as to facilitate passing from one figure to another.

The different parts shown in the figures are not necessarily shown according to a uniform scale, to make the figures more legible.

The different possibilities (variants and embodiments) must be understood as not being exclusive of one another and may be combined with one another.

### DETAILED DISCLOSURE OF PARTICULAR EMBODIMENTS

The different example embodiments described hereinafter comprise resistive thermal detectors of the bolometer type. However, these examples may also apply to any type of resistive thermal detector other than a bolometer, for example any resistor variable with temperature.

Reference is made first of all to FIG. 2, which shows an electronic circuit 100 for biasing and reading a bolometer 102 of a pixel 101 of an infrared imager, according to a first embodiment.

The elements of the electronic circuit 100 are here all produced within the pixel 101 comprising the bolometer 102 that the electronic circuit 100 is intended to bias and read. The bolometer 102 comprises a first terminal to which a voltage Vdt is applied and a second terminal electrically connected to the drain of a first MOS transistor 104, here of the PMOS type, forming part of the electronic circuit 100. A supply voltage Vdd is applied to the source of the first MOS transistor 104.

The electronic circuit 100 also comprises a second MOS transistor 106 of the type opposite to the first transistor 104, that is to say here of the NMOS type. A voltage Veb is applied to the source of the second MOS transistor 106. The gate of the second MOS transistor 106 is electrically connected to the drain of the first MOS transistor 104. Finally, the drain of the second MOS transistor 106 is electrically connected to a bus 110 by means of a switch 108.

The matrix of the infrared imager comprises other pixels, not shown and similar to the pixel 101, that is to say comprising a bolometer similar to the bolometer 102 and an electronic biasing and reading circuit similar to the electronic circuit 100. The pixels arranged on the same column as the pixel 101 are also electrically connected to the bus 110 so that all the measurement signals outputted by the pixels of this column are outputted to a processing circuit 112 by means of the bus 110.

The first MOS transistor 104 forms means for the current biasing of the bolometer 102, which then has an average biasing current Io of substantially constant value passing through it. A temperature fluctuation in the scene results in a variation in the resistance Ro of the bolometer 102 and therefore a variation in the voltage Vo at the terminals of the bolometer 102.

The voltage Vbolo (with Vbolo−Vo+Vdt), corresponding to the potential at the point of intersection between the bolometer 102 and the drain of the first MOS transistor 104, is read on the gate of the second MOS transistor 106. This voltage Vbolo is then converted into a current Imeasure by the transconductance of the second MOS transistor 106. The switch 108 is intended to be switched to the closed position when the measurement current is read, that is to say when it is wished to read the signal measured by the pixel 101.

The voltage Veb applied to the source of the second MOS transistor 106 is controlled and fixed so as to put the second MOS transistor 106 at the saturation limit. This is because the saturation regime of the second MOS transistor 106 enables it to accept variations in current while keeping its drain voltage floating (the drain of this MOS is connected, when the measurement of the sensor is acquired and by means of the switch 108 then closed, to the circuit 112 processing the measurement current outputted by the pixel 101, and for example to a negative input of an amplifier connected as an integrator forming part of the current processing circuit 112; it is this amplifier that fixes the voltage at its negative input). However, it is sought for the second MOS transistor 106 to be in saturation while supplying only the lowest possible current for the purpose of obtaining a very small common mode and thus keeping only the small fluctuations in the current that correspond to the fluctuations in the scene temperature measured. This is the reason why the voltage Veb is controlled and fixed so as to put the second MOS transistor 106 at the saturation limit.

The measurement current Iₘₑₐₛᵤᵣₑ, representing temperature variations measured by the bolometer 102 and corresponding to the current Ids of the second MOS transistor 106, is therefore such that:

$$Imeasure = \frac{μCox}{2} \cdot \frac{W}{L} \cdot {( Vgs - Vt )}^{2} \qquad ( 1 )$$

with:

Cox: capacitance of the gate oxide per unit of surface of the second MOS transistor 106;

W: width of the channel of the second MOS transistor 106;

μ: mobility of the carriers of the second MOS transistor 106;

L: length of channel of the second MOS transistor 106;

Vgs: gate-source voltage of the second MOS transistor 106;

Vt: threshold voltage of the second MOS transistor 106.

However, Vgs=Vbolo−Veb.

In addition, Vbolo=Io×Ro

This therefore gives:

$$Imeasure = \frac{μCox}{2} \cdot \frac{W}{L} \cdot {( Io \cdot Ro - Veb - Vt )}^{2} \qquad ( 2 )$$

Thus, when the bolometer 102 is subjected to the scene temperature variation, this gives rise to a variation in its electrical resistance Ro, which results in a variation in the measurement current Imeasure.

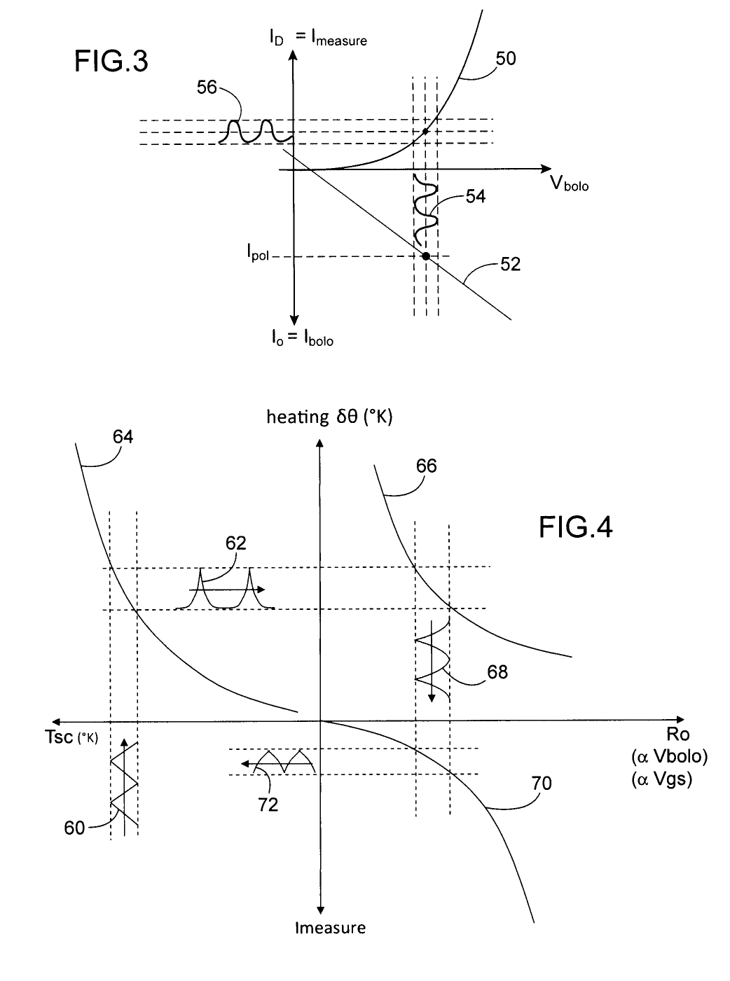

The curve 50 shown in FIG. 3 corresponds to the relationship between the value of the current Imeasure as a function of the value of Vbolo, that is to say represents graphically equation (2). The curve 52 represents the relationship between the value of the biasing current Io=Ibolo as a function of the value of Vbolo, obtained by Ohm's law. For an operating point of the second MOS transistor 106, as shown in FIG. 3, a measurement of a temperature variation by the bolometer 102 then results in a variation 54 in the voltage Vbolo around the operating point. This variation 54 is then converted by the second MOS transistor 106 into a variation 56 in the current Imeasure. The link between the voltage Vbolo and the measurement current Imeasure is not linear but quadratic (equation (2)).

This relationship can also be interpreted by the passage from Vbolo to Imeasure via the transconductance

$$gm = \frac{δ Imeasure}{δ Vgs} = \frac{δ Imeasure}{δ Vbolo}$$

of the second

MOS transistor 106. In this case, equation (2) can also be written:

$$Imeasure = \frac{gm}{2} \cdot ( Vbolo - Veb - Vt )$$

With respect to the pixel 10 of the prior art previously described, the relationship between the change in the measurement current and the scene temperature is reversed. This is because, in the pixel 101, when the scene temperature increases, the bolometric resistance Ro decreases, which causes the reduction in the voltage Vbolo (the current biasing of the bolometer 102 by the first MOS transistor 104 provides a constant current Io), which itself involves a reduction in the current Imeasure via the second MOS transistor 106, and vice versa when the scene temperature decreases. Thus, except if a reversal is intentionally inserted, the cold zones are represented by light grey levels and the hot zones by dark grey levels in the image obtained by the infrared image comprising a matrix of pixels similar to the pixel 101.

In addition, contrary to the former architecture of the pixel 10, the structure of the electronic circuit 100 for biasing and reading the bolometer 102 attenuates the non-linearity of the relationship between the heating θ of the bolometer 102 and the scene temperature Tsc.

FIG. 4 shows graphically the various conversion operations performed within the pixel 101, from the infrared flow captured by the bolometer 102 as far as the measurement current Imeasure obtained at the output of the electronic circuit 100.

The variations in the temperature of the scene Tsc to be measured are represented by the curve 60. Given that the scene may be assimilated to a black body, the infrared flow 62 corresponding to this temperature variation 60 is obtained by the curve 64 representing the relationship between the value of the heating δθ and the temperature Tsc for such a black body, this curve being exponential in Tsc. It can be seen in FIG. 4 that this relationship 64 between the value of the heating 50 and the temperature Tsc gives a concave curvature to the temperature variation signal 60, this curvature being found on the signal of the infrared flow 62.

The curve 66 shows the relationship between the resistance Ro of the bolometer 102 and the heating 60 received by the bolometer 102, giving the value of the resistance Ro of the bolometer 102 as a function of the infrared flux received. This curve 66 is proportional to the exponential of the inverse of the heating. The bolometer 102 behaves thermally as a thermal absorbent, that is to say as a thermal resistor with negative coefficient. The variation in Ro obtained corresponding the infrared flux 62 is represented by the curve 68. It can be seen in FIG. 4 that the relationship 66 between the resistance Ro of the bolometer 102 and the heating δθ received by the bolometer 102 gives a convex curvature to the variation signal of the infrared flux 62, attenuating the concave curvature given by the relationship 64 between the value of the heating 50 and the temperature Tsc.

The variation in Ro is directly proportional to the variation in the voltage Vbolo and therefore also to the variation in the voltage Vgs at the terminals of the second MOS transistor 106. Thus the curve 68 also represents, to within a constant multiplying factor, the variation in the voltage Vgs between the gate and source of the second MOS transistor 106.

In a variant, the two MOS transistors may be of the same type. An accentuation of the concave curvature given by the relationship 64 is then obtained.

The curve 70 represents the relationship between the resistance Ro of the bolometer 102 and the value of the current Imeasure outputted by the pixel 101. This curve 70 is proportional to the coefficient Vgs², with Vgs corresponding to the gate-source voltage of the second MOS transistor 106. The variation in Imeasure obtained corresponding to the variation in Ro 68 is represented by the curve 72. It can be seen in FIG. 4 that the relationship 70 between the resistance Ro of the bolometer 102 and the current Imeasure gives a convex curvature to the variation signal for the voltage Vgs. Thus the curvature of the variation signal for Imeasure 72 obtained approaches that of the initial signal 60 for the scene temperature measured.

The structure of the electronic circuit 100 makes it possible to supply to the bolometer 102 an average current Io necessary by virtue of the first MOS transistor 104. In addition, the second MOS transistor 106 used for converting the voltage of the bolometer 102 into current has a drain-source current Ids passing through it weak enough to attenuate the noise thereof but strong enough to contain the fluctuations representing the useful information supplied by the bolometer 102.

Given that the voltage Veb applied to the source of the second MOS transistor 106 is chosen so that the measurement current Imeasure does not have a useless common mode, and therefore that only the useful variations of the current are sent over the bus 110, this voltage Veb makes a voltage base clipping of the bolometer 102. Such an electronic circuit 100 therefore makes it possible to reduce the noise and to replace the base clipping structure 18 situated at the column head in the pixel 10 of the prior art.

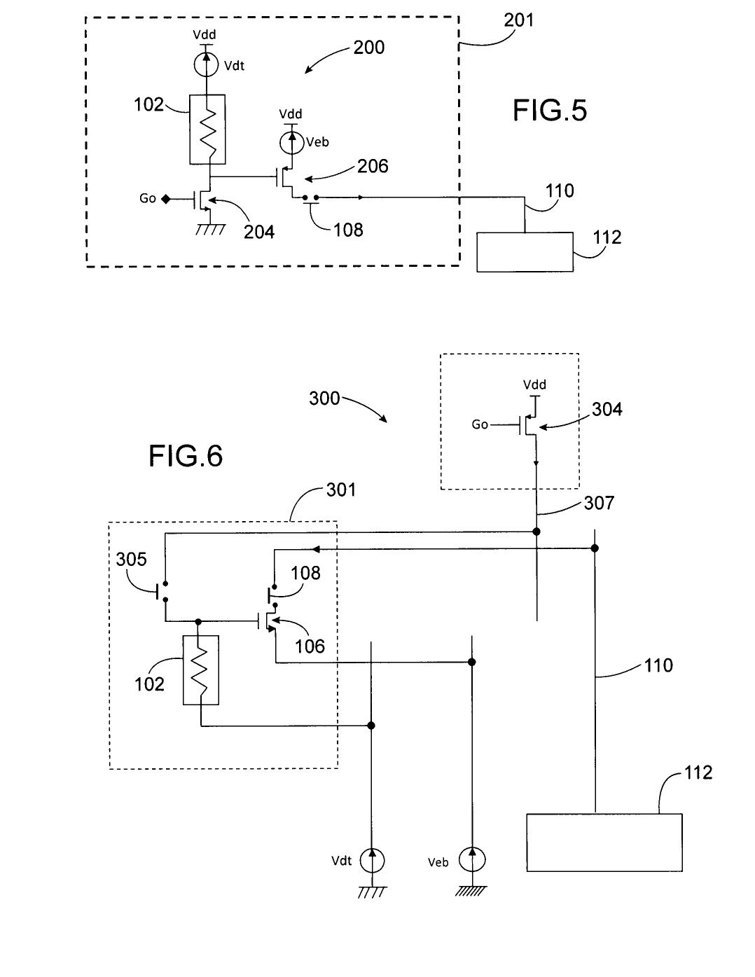

Reference is made to FIG. 5, which shows an electronic circuit 200 for biasing and reading a bolometer 102 of a pixel 201 of an infrared imager according to a variant of the first embodiment.

Compared with the electronic circuit 100 previously described, the current biasing of the bolometer 102 is here provided by a first MOS transistor 204 of the NMOS type. In addition, unlike the electronic circuit 100 in which the first MOS transistor 104 had its source electrically connected to the supply voltage Vdd and its drain electrically connected to a terminal of the bolometer 102 (the other terminal of the bolometer 102 being electrically connected to the potential Vdt), the first MOS transistor 204 has it source electrically connected to earth and its drain electrically connected to a terminal of the bolometer 102. The other terminal of the bolometer 102 is electrically connected to the potential Vdt itself connected to the supply voltage Vdd.

The electronic circuit 200 also comprises a second MOS transistor 206 of the PMOS type serving to convert the voltage of the bolometer 102 into current. As in the electronic circuit 100, a voltage Veb is applied to the source of the second MOS transistor 206. This voltage Veb is also connected to the supply voltage Vdd. As with the electronic circuit 100, the drain of the second MOS transistor 206 is electrically connected to the switch 108 making it possible to output the measurement current Imeasure on the bus 110.

The operating principle of the electronic biasing and reading circuit 200 is similar to that of the electronic circuit 100.

In a variant of the electronic circuits 100 and 200, it is possible for the biasing and conversion MOS transistors to be of the same type, NMOS or PMOS. For transistors of the PMOS type, such an electronic circuit would correspond to the circuit 100 previously described but in which the NMOS transistor 106 is replaced by the PMOS transistor 206, a voltage Veb being applied to the source of the second PMOS transistor 206, this voltage Veb also being connected to the supply voltage Vdd as shown in FIG. 5. For NMOS-type transistors, such an electronic circuit would correspond to the circuit 200 previously described but in which the PMOS transistor 206 is replaced by the NMOS transistor 106 having, as in FIG. 2, a voltage Veb applied to its source.

Another electronic circuit 300 for biasing and measuring a bolometer 102 of a pixel 301 of an infrared imager according to a second embodiment is described in relation to FIG. 6.

Unlike the electronic biasing and reading circuits 100 and 200 previously described, the elements of the electronic circuit 300 are not all disposed within the pixel 301. This is because, in this electronic circuit 300, the current biasing of the bolometer 102 is provided by a first MOS transistor 304, here of the PMOS type, disposed at the column head of the matrix of pixels. As in the electronic circuit 100, the source of the first MOS transistor 304 is electrically connected to the supply voltage Vdd. The first MOS transistor 304 serves here for current biasing all the bolometers of the pixels situated on the same column as the pixel 301. Thus the drain of the first MOS transistor 304 is electrically connected to a bus 307 to which there are also electrically connected each of the bolometers of the pixels situated on the same column as the pixel 301 by means of a switch. In the example in FIG. 5, the bolometer 102 is electrically connected to the bus 307 by means of a switch 305. The bolometer 102 is also electrically connected, at a second terminal, to a potential Vdt, also common to all the pixels situated on the same column as the pixel 301.

Like the electronic circuit 100, the electronic circuit 300 comprises the second MOS transistor 106 of the NMOS type. A voltage Veb, also common for all the pixels in the column, is applied to the source of the second MOS transistor 106. The gate of the second MOS transistor 106 is electrically connected to the electrical connection between the switch 305 and the bolometer 102. Finally, the drain of the second MOS transistor 106 is electrically connected to the bus 110 by means of the switch 108. In a similar manner to the electronic circuit 100, the second MOS transistor 106 of the electronic circuit 300 makes it possible to read the voltage Vbolo and to convert it into a current Imeasure through its transconductance. The switch 108 is switched into the closed position when the measurement current Imeasure is read.

The functioning of the electronic circuit 300 (current biasing of the bolometer 102 and conversion of the voltage of the bolometer 102 into current) is similar to that of the electronic circuit 100, except that the switch 305 is added in the pixel in order to bias the correct bolometer at the correct moment.

Compared with the electronic circuits 100 and 200, the electronic circuit 300 according to the second embodiment has the advantage of having a structure requiring only one transistor to be implemented within the pixels (the second MOS transistor 106).

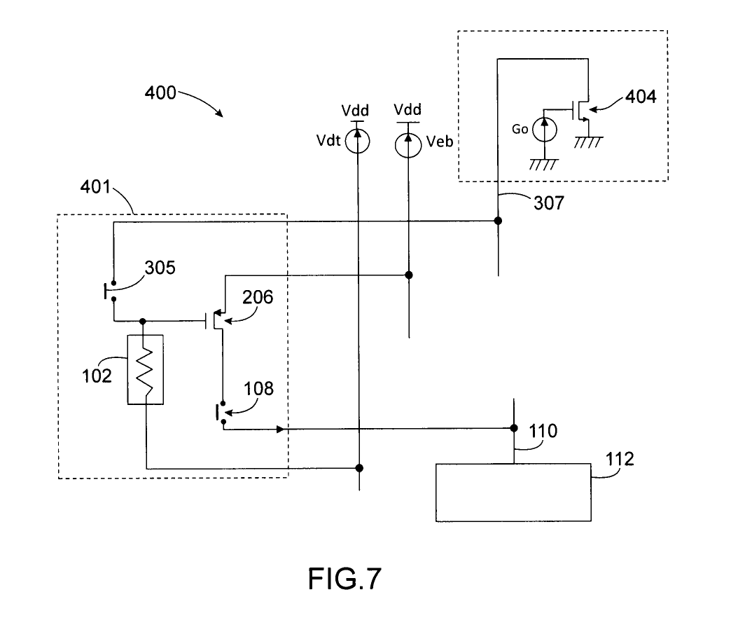

Reference is made to FIG. 7, which shows an electronic circuit 400 for biasing and reading a bolometer 102 of a pixel 401 of an infrared imager according to a variant of the second embodiment.

Compared with the electronic circuit 300 previously described, the current biasing of the bolometer 102 is here provided by a first MOS transistor 404 of the NMOS type which, like the first MOS transistor 304, is arranged at the pixel column head. In addition, unlike the electronic circuit 300 in which the first MOS transistor 304 had its source electrically connected to the supply voltage Vdd and its drain electrically connected to the bolometer 102 by means of the switch 305 and the bus 307 (the other terminal of the bolometer 102 being connected to the potential Vdt) the first MOS transistor 404 has its source electrically connected to earth and its drain electrically connected to the bolometer 102 by means of the switch 305 and the bus 307. The other terminal of the bolometer 102 is electrically connected to the potential Vdt itself connected to the supply voltage Vdd.

Like the electronic circuit 200, the electronic circuit 400 comprises the second MOS transistor 206 of the PMOS type serving to convert the voltage of the bolometer 102 into current. As in the electronic circuit 200, a voltage Veb is applied to the source of the second MOS transistor 206. This voltage Veb is also connected to the supply voltage Vdd. Finally, as with the electronic circuit 200, the drain of the second MOS transistor 206 is electrically connected to the switch 108 making it possible to output the measurement current Imeasure on the bus 110.

The operating principle of the electronic biasing and reading circuit 400 is similar to that of the electronic circuit 300.

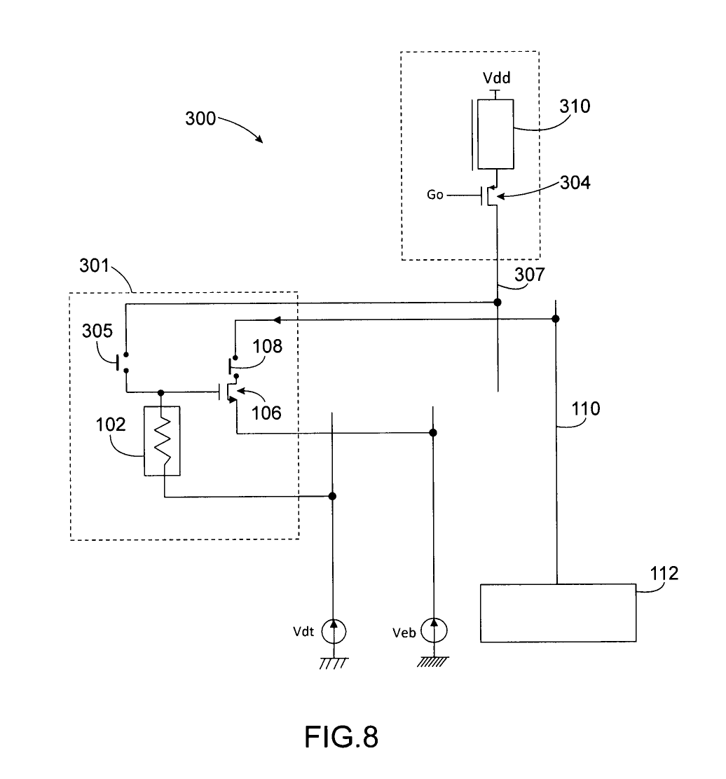

In another variant embodiment shown in FIG. 8, it is possible to implement the electronic circuit 300 for biasing and reading the bolometer 102 so that it comprises a thermalised bolometer 310 interposed between the source of the first MOS transistor 304 and the supply voltage Vdd.

This is because, in the electronic circuits 100 to 400 previously described, the means of biasing the bolometer 102 comprise solely a current source, which amounts to say that the average gate voltage of the second MOS transistor 106 or 206 making the voltage/current conversion is always constant. Given that the base clipping voltage Veb is also constant, there will be a constant average voltage Vgs and therefore an average measurement current Imeasure that is also constant. This means that the voltage base clipping is fixed and does not take account of the operating temperature. When the temperature increases, the bolometer 102 undergoes heating and the average value of its resistance decreases, which increases the common mode of the current passing through it.

Thus, in order to adapt to this heating phenomenon, it is possible to use a thermalised bolometer 310 as shown in FIG. 8. This bolometer 310 is coupled to the current biasing means of the electronic circuit 300. Thus the average biasing current of the bolometer 102 follows the temperature increase thereof. Consequently the voltage Vgs of the second conversion MOS transistor 106, and therefore the average measuring current Imeasure outputted, also follow this heating.

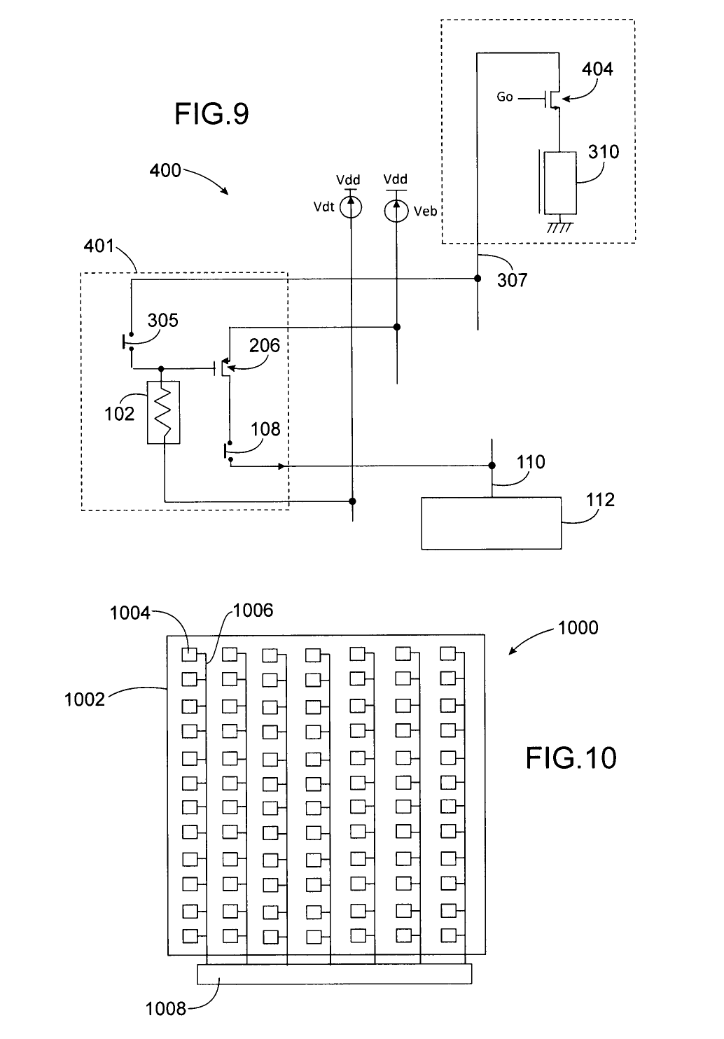

Such a thermalised bolometer 310 may also be added to the electronic circuit 400 as shown in FIG. 9, which is then coupled to the current biasing means of the electronic circuit 400, between the first MOS transistor 404 and earth.

PMOS transistors being generally less noisy than NMOS transistors, it is advantageous to implement, in an infrared imager, the electronic circuits for biasing and reading bolometers 200 and 400 previously described that comprise a second PMOS transistor making a voltage/current conversion of the measurement made.

An imager 1000, for example an infrared camera, is shown partially in FIG. 10. This imager 1000 comprises a matrix 1002 of pixels 1004. Each of the pixels 1004 can correspond to one of the pixels 101, 201, 301 and 401 previously described. Each pixel 1004 comprises a bolometer and an electronic biasing and reading circuit for example similar to the circuit 100 previously described. The electronic biasing and reading circuits in the same column of pixels are electrically connected to a circuit 1008 for processing the measurement signals and making it possible to restore the image captured by the pixels 1004, by means of a bus 1006.

1. An electronic circuit for biasing and reading at least one resistive thermal detector, comprising:
biasing means able to bias the resistive thermal detector by making a biasing current of substantially constant value flow in the resistive thermal detector when the electrical resistance thereof varies;
conversion means able to convert a voltage at the terminals of the resistive thermal detector into a current, comprising at least one MOS-type transistor the gate of which is electrically connected to one of the terminals of the resistive thermal detector;
means of generating a base clipping voltage electrically connected to the source of the MOS-type transistor of the conversion means.

2. The electronic circuit according to claim 1, in which the biasing means comprise at least one first MOS-type transistor the source or drain of which is electrically connected to said one of the terminals of the resistive thermal detector, the MOS-type transistor of the conversion means being referred to as the second transistor.

3. The electronic circuit according to claim 2, in which the first MOS-type transistor is an NMOS transistor and the second MOS-type transistor is a PMOS transistor, or in which the first MOS-type transistor is a PMOS transistor and the second MOS-type transistor is an NMOS transistor.

4. The electronic circuit according to claim 2, in which the first MOS-type transistor and the second transistor are transistors of the same type, PMOS or NMOS.

5. The electronic circuit according to claim 2, also comprising at least one switch electrically connected to the second MOS-type transistor and able to establish and interrupt a flow of current between the second MOS-type transistor and an output on which the current outputted by the conversion means is intended to be sent.

6. An electronic imager comprising a matrix of pixels each pixel comprising at least one resistive thermal detector, and also comprising a plurality of electronic circuits for biasing and reading at least one resistive thermal detector according to claim 1.

7. The electronic imager according to claim 6, in which each electronic biasing and reading circuit is associated with a single pixel comprising a resistive thermal detector intended to be biased and read by said electronic biasing and reading circuit, the biasing means and the conversion means of said electronic biasing and reading circuit being disposed in said pixel.

8. The electronic imager according to claim 6, in which each electronic biasing and reading circuit is associated with several pixels each comprising a resistive thermal detector intended to be biased and read by said electronic biasing and reading circuit, each electronic biasing and reading circuit comprising several conversion means, each of said conversion means being able to convert a voltage at the terminals of the resistive thermal detector of one of said pixels into a current and being disposed in said one of said pixels, and in which the biasing means of each electronic biasing and reading circuit are common to several pixels and are able to bias the resistive thermal detectors of said pixels by causing a biasing current of substantially constant value to flow in the resistive thermal detectors of said pixels when there is a variation in the electrical resistance of the resistive thermal detectors of said pixels.

9. The electronic imager according to claim 8, in which the biasing means of each electronic biasing and reading circuit are disposed outside said pixels.

10. The electronic imager according to claim 8, in which each of said pixels also comprises at least one switch able to establish and interrupt a flow of said current of substantially constant value between the resistive thermal detector of said pixel and the biasing means of said pixel.

11. The electronic imager according to claim 7, in which the biasing means of each electronic biasing and reading circuit also comprise at least one thermalised resistive thermal detector able to modify the value of said biasing current.

12. The electronic imager according to claim 6, in which the resistive thermal detectors are able to measure an infrared radiation.

13. The electronic imager according to claim 6, in which the resistive thermal detectors are bolometers.

14. A method of measuring a temperature by means of a resistive thermal detector, comprising at least the steps of:
biasing the resistive thermal detector by causing a biasing current of substantially constant value to flow in the resistive thermal detector when there is a variation in the electrical resistance of the resistive thermal detector;
reading a voltage at the terminals of the resistive thermal detector exposed to the temperature to be measured;
converting the voltage read at the terminals of the resistive thermal detector by means of an MOS-type transistor the gate of which is electrically connected to one of the terminals of the resistive thermal detector, into a current corresponding to the temperature measurement, a base clipping voltage being applied to the source of the MOS-type transistor.
